(19) United States
(12) Patent Application Publication
(10) Pub. No.: US 2011/0080353 A1
(43) Pub. Date: Apr. 7, 2011

(54) Electrode pattern for touch screen, driver for touch screen, and touch screen

(75) Inventors: Shin Jae Kang, Gunpo (KR); Kyung Uk Kim, Seoul (KR); Won Jin Baek, Anyang (KR)

(73) Assignee: SAMSUNG ELECTRO-MECHANICS CO., LTD., Suwon (KR)

(21) Appl. No.: 12/654,425

(22) Filed: Dec. 18, 2009

(30) Foreign Application Priority Data
Oct. 7, 2009 (KR) 10-2009-0095081

(51) Int. Cl. G06F 3/041; H05K 1/00

(52) U.S. Cl. 345/173; 174/250

(57) ABSTRACT

Disclosed is a touch screen to accurately receive a user selection by applying differential signals to the electrode patterns of a touch screen, each having a different capacitance.

### CROSS-REFERENCE TO RELATED APPLICATIONS

This application claims the priority of Korean Patent Application No. 10-2009-0095081 filed on Oct. 7, 2009, in the Korean Intellectual Property Office, the disclosure of which is incorporated herein by reference.

### BACKGROUND OF THE INVENTION

1. Field of the Invention

The present invention relates to a touch screen and, more particularly, to a touch screen capable of accurately receiving a user selection by applying differential signals to electrode patterns of a touch screen, each having a different capacitance.

2. Description of the Related Art

Recently, as electronic devices have become lighter, thinner, shorter, and smaller, a touch screen input scheme having the advantages of allowing for a simple and convenient input procedure tends to be commonly employed for personal information terminals such as PDAs, PMPs, mobile phones, etc., or a banking information terminals such as ATMs.

The touch screen input scheme include various input schemes such as a resistance film type input scheme, a capacitance type input scheme, an infrared scheme, an ultrasonic scheme, etc. Among those schemes, the capacitance scheme, allowing for driving at a low power level and having high transparency, is widely used for mobile personal information terminals such as PDAs, PMPs, mobile phones, etc., and high picture quality display devices of HD class or higher.

Generally, the capacitance scheme is able to receive user input through an overlap between two conductive regions formed according to orthogonal crossing of electrode patterns formed on dual-layered indium tin oxide (ITO) films or through the coupling of the two conductive regions.

Namely, a driver signal is applied to one side of one of electrode patterns formed on one ITO film, and a change in capacitance is detected at one side of another electrode pattern formed on another ITO film, to thereby determine the presence or absence of a user contact.

However, in the capacitance type touch screen, noise is generated due to interference between respective driving liens and detection lines, and because the large ITO films are exposed, they are affected by external noise.

Such noise affects the amount of a change in a corresponding voltage, hindering accurate determining of the presence or absence of user contact.

### SUMMARY OF THE INVENTION

An aspect of the present invention provides a touch screen capable of accurately receiving a user selection by applying differential signals to electrode patterns of a touch screen each having a different capacitance.

According to an aspect of the present invention, there is provided an electrode pattern for a touch screen, including: a first electrode pattern part having a plurality of row patterns disposed in rows, each of the plurality of row patterns having a plurality of pad positions prepared at pre-set intervals, the odd numbered row patterns, among the plurality of row patterns, having an electrode pad with a certain area formed at each odd-numbered pad position, and the even-numbered row patterns, among the plurality of row patterns, having an electrode pad with a certain area formed at each even-numbered pad position; and a second electrode pattern part having a plurality of column patterns disposed in columns on a lower surface of the first electrode pattern part, each of the plurality of column patterns having a plurality of pad positions prepared at pre-set intervals and facing the plurality of pad positions of the row patterns, the odd numbered column patterns, among the plurality of column patterns, having an electrode pad with a certain area formed at each odd-numbered pad position, and the even-numbered column patterns, among the plurality of column patterns, having an electrode pad with a certain area formed at each even-numbered pad position.

A dielectric may be disposed between the first and second electrode pattern parts.

The area of the electrode pad of the first electrode pattern part and that of the second electrode pattern part may be the same.

The area of an odd-numbered electrode pad of the first electrode pattern part and that of the even-numbered electrode pad of the first electrode pattern part may be the same.

The area of the odd-numbered electrode pad of the second electrode pattern part and that of the even-numbered electrode pad of the second electrode pattern part may be the same.

According to an aspect of the present invention, there is provided a driver for driving a touch screen, including: a signal providing unit providing a differential signal having a pre-set phase difference by at least a pair of row patterns among electrode patterns formed as a plurality of row patterns and a plurality of column patterns cross; a detection unit detecting capacitance by at least a pair of row patterns among the plurality of column patterns; and a controller controlling the signal providing unit to provide the differential signal and the detection unit to detect capacitance.

The signal providing unit may include: a signal generator generating a phase difference signal having a pre-set phase difference; a signal modulator modulating the differential signal to supply the phase difference signal from the signal generator to the electrode patterns; and a first multiplexer selecting at least a pair of row patterns from among the row patterns of the electrode patterns and providing the differential signal from the signal modulator by the selected pair of row patterns under the control of the controller.

The detection unit may include: a second multiplexer selecting at least a pair of column patterns from among the column patterns of the electrode patterns and receiving capacitance by the selected pair of column patterns under the control of the controller; a Q-V converter converting the received capacitance into a detection signal having a voltage according to the capacitance; a noise canceler canceling detection signal noise transferred from the Q-V converter; and an A/D converter converting the detection signal, whose noise has been canceled by the noise canceler, into a digital signal.

The controller may include: a channel scan logic unit setting the scanning of the electrode patterns; and a channel decoder controlling the signal providing unit to select row patterns and the detection unit to select column patterns according to the setting of the channel scan logic unit.

The first multiplexer may select mutually adjacent row patterns as a pair of row patterns among the plurality of row patterns.

The second multiplexer may select mutually adjacent column patterns as a pair of column patterns among the plurality of column patterns.

According to another aspect of the present invention, there is provided a touch screen including: a first electrode pattern part having a plurality of row patterns disposed in rows, each of the plurality of row patterns having a plurality of pad positions prepared at pre-set intervals, the odd numbered row patterns, among the plurality of row patterns, having an electrode pad with a certain area formed at each odd-numbered pad position, and the even-numbered row patterns, among the plurality of row patterns, having an electrode pad with a certain area formed at each even-numbered pad position; a second electrode pattern part having a plurality of column patterns disposed in columns on a lower surface of the first electrode pattern part, each of the plurality of column patterns having a plurality of pad positions prepared at pre-set intervals and facing the plurality of pad positions of the row patterns; and a driving circuit providing a differential signal having a pre-set phase difference by at least a pair of row patterns among the plurality of row patterns of the electrode patterns.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic block diagram showing the configuration of a touch screen according to an exemplary embodiment of the present invention;

FIG. 2 illustrates the configuration of a first electrode pattern part of electrode patterns employed for the touch screen according to an exemplary embodiment of the present invention;

FIG. 3 illustrates the configuration of a second electrode pattern part of electrode patterns employed for the touch screen according to an exemplary embodiment of the present invention;

FIG. 4 illustrates the configuration of electrode patterns employed for the touch screen according to an exemplary embodiment of the present invention; and

FIG. 5 illustrates the driving of electrode patterns employed for the touch screen according to an exemplary embodiment of the present invention.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity, and the same reference numerals will be used throughout to designate the same or like components.

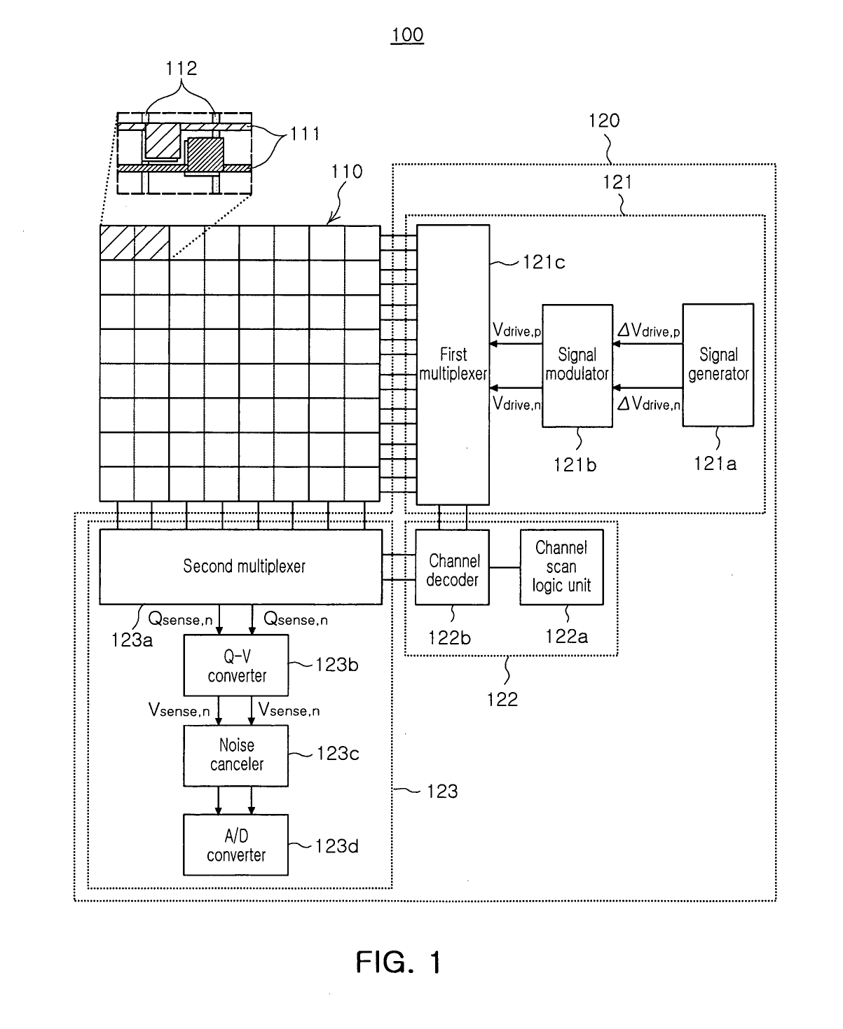

FIG. 1 is a schematic block diagram showing the configuration of a touch screen according to an exemplary embodiment of the present invention.

With reference to FIG. 1, a touch screen 100 according to an exemplary embodiment of the present invention may include an electrode pattern 110 and a driving circuit 120.

The electrode pattern 110 may include first and second electrode pattern parts 111 and 112. The first electrode pattern part 111 may have a plurality of row patterns, and the second electrode pattern part 112 may have a plurality of column patterns. The first and second electrode pattern parts 111 and 112 may formed to cross each other.

Namely, the electrode pattern 110 may include a plurality of patterns formed in rows and columns, and the plurality of row patterns of the first electrode pattern part 111 are disposed in rows and the plurality of column patterns of the second electrode pattern part 112 are disposed in columns on a lower surface of the plurality of row patterns such that they cross each other.

The electrode pattern 110 will now be described in detail.

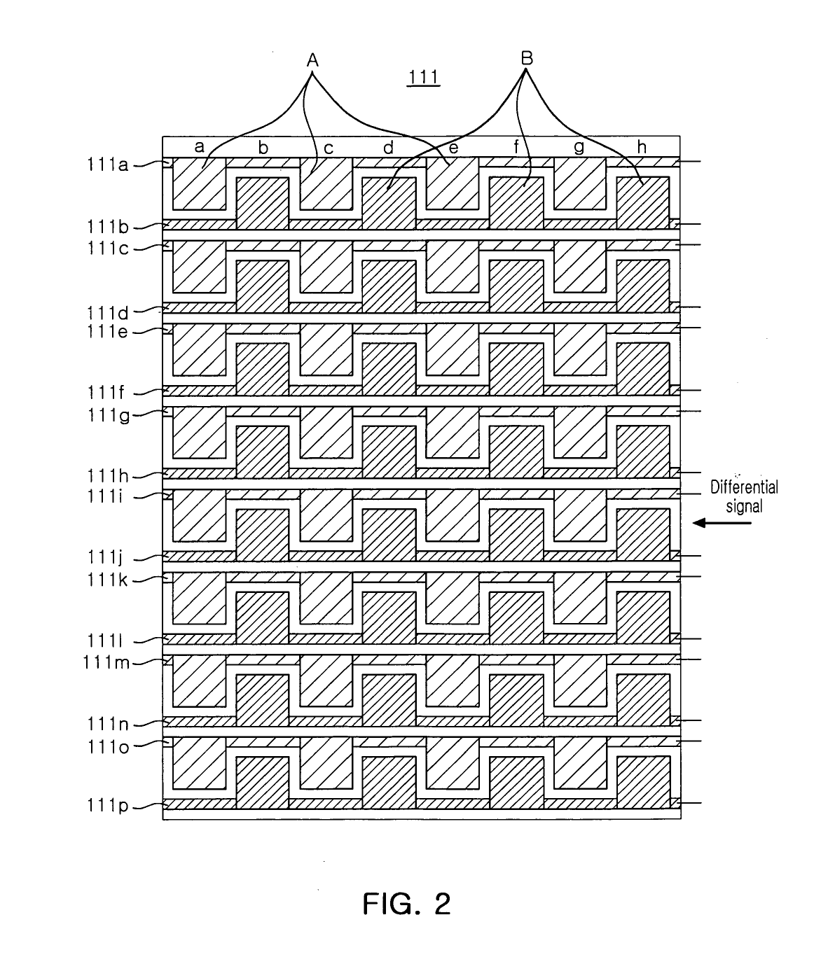

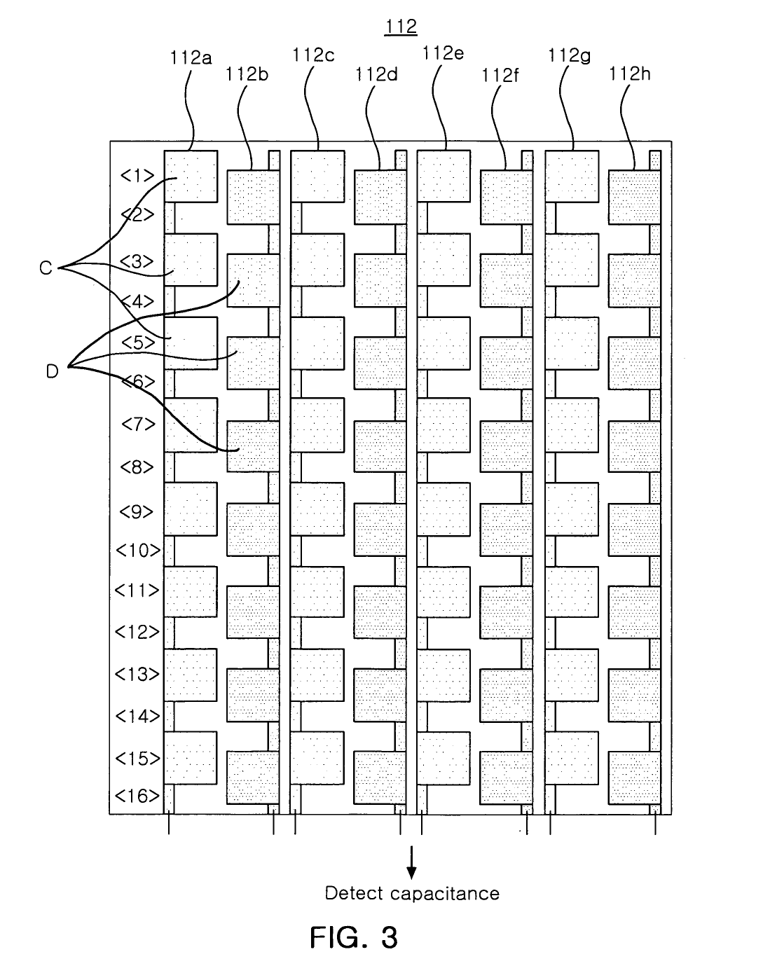

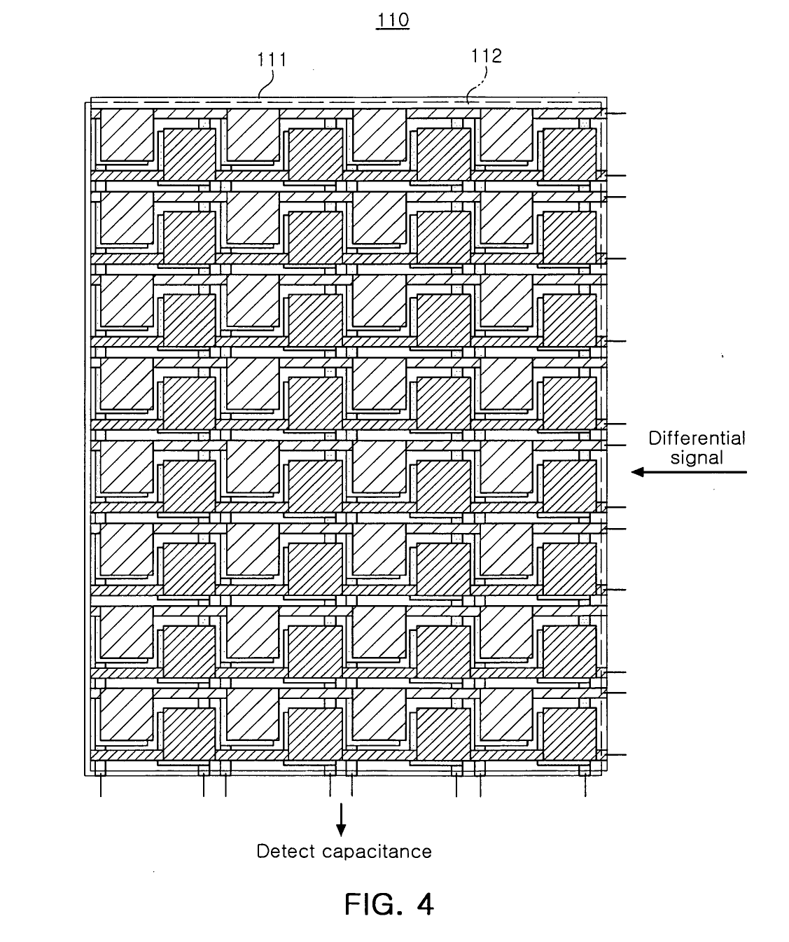

FIG. 2 illustrates the configuration of a first electrode pattern part of electrode patterns employed for the touch screen according to an exemplary embodiment of the present invention. FIG. 3 illustrates the configuration of a second electrode pattern part of electrode patterns employed for the touch screen according to an exemplary embodiment of the present invention. FIG. 4 illustrates the configuration of electrode patterns employed for the touch screen according to an exemplary embodiment of the present invention.

With reference to FIG. 2, the first electrode pattern part 111 may include, for example, row patterns 111a to 111p disposed in 16 rows. The 16 row patterns 111a to 111p have eight electrode pad positions a to h formed at pre-set intervals, respectively, and electrode pads (A) with a certain area may be prepared at the first, third, fifth, and seventh electrode pad positions (a, c, e, g) in the first row pattern 111a. The second row pattern 111b may have electrode pads (B) with a certain area at the second, fourth, sixth, and eighth electrode pad positions (b, d, f, h).

The formation of electrode pads may be applied to the subsequent row patterns. Namely, the third, fifth, seventh, ninth, eleventh, thirteenth, and fifteenth row patterns (111c,111e,111g,111i,111k,111m,111o) may have the electrode pads (A) with a certain area at the first, third, fifth, and seventh electrode pad positions (a, c, e, g) like the first row pattern 111a. Also, the fourth, sixth, eighth, tenth, twelfth, fourteenth, and sixteenth row patterns (111d,111f,111h,111j,111l,111n,111p) may have the electrode pads (B) with a certain area at the second, fourth, sixth, and eighth electrode pad positions (b, d, f, h) like the second row pattern 111b.

The plurality of row patterns as described above may receive a differential signal from the driving circuit 120. In this case, the differential signal may have a pre-set phase difference, and accordingly, the differential signal may be provided by at least a pair of row patterns. For example, the differential signal may include a first signal having a certain phase and a second signal having a pre-set phase difference from the first signal. The first signal may be provided to one end of the first row pattern 111a, and the second signal may be provided to one end of the second row pattern 111b. As described above, the differential signal may be provided to one end of each of the third and fourth row patterns 111c and 111d, and in this case, the differential signal may be sequentially provided to the third and fourth row patterns 111c and 111d after being provided to one end of each of the first and second row patterns 111a and 111b.

The differential signal may be provided by at least a pair of row patterns, or may be simultaneously provided to two pairs of row patterns or three or more pairs of row patterns.

With reference to FIG. 3, the second electrode pattern part 112 may include, for example, column patterns 112a to 112h disposed in eight columns. The eight column patterns 112a to 112h have sixteen electrode pad positions <1>to <16>formed at pre-set intervals. The first column pattern 112a may have electrode pads (C) with a certain area at first, third, fifth, seventh, ninth, eleventh, thirteenth, and fifteenth electrode pad positions (<1>,<3>,<5>,<7>,<9>,<11>,<13>,<15>). Also, the second column pattern 112b may have electrode pads (D) with a certain area at second, fourth, sixth, eighth, eleventh, fourteenth and sixteenth electrode pad positions (<2>,<4>,<6>,<8>,<10>,<12>,<14>,<16>).

The formation of the electrode pads may be applied to subsequent column patterns. Namely, the third, fifth, and seventh column patterns may have the electrode pads (C) with a certain area at the first, third, fifth, seventh, ninth, tenth, thirteenth, and fifteenth electrode pad positions (<1>,<3>,<5>,<7>,<9>,<11>,<13>,<15>) like the first column pattern 112a. Also, the fourth, sixth, and eighth column patterns 112d, 112f, and 112h may have the electrode pads (D) with a certain area at the second, fourth, sixth, eighth, eleventh, twelfth, fourteenth, and sixteenth electrode pad positions (<2>,<4>,<6>,<8>,<10>,<12>,<14>,<16>) like the second column pattern 112b.

The plurality of column patterns may receive a detected capacitance from the driving circuit 120. In this case, the capacitance may be detected by at least a pair of patterns. For example, capacitance can be simultaneously detected from one end of the first column pattern 112a and from one end of the second column pattern 112b. As described above, the capacitance may be detected from one end of the third and fourth column patterns 112c and 112d. In this case, after the capacitance is detected from one end of the first and second column patterns 112a and 112b, the capacitance is sequentially detected from one end of the third and fourth column patterns 112c and 112d.

The capacitance detection as described above may be performed by at least a pair of column patterns, or may be performed simultaneously by two pairs of column patterns, or three or more pairs of column patterns.

With reference to FIG. 4, the first pattern part 111 illustrated in FIG. 2 and the second pattern part 112 illustrated in FIG. 3 may be disposed in an overlapping manner. In this case, the first and second pattern parts 111 and 112 may be fabricated as transparent electrode patterns so as to be applied to a touch screen, and a transparent film or a dielectric such as glass having a certain dielectric constant may be disposed between the first and second pattern parts 111 and 112 in order to detect user contact. Accordingly, capacitance by the differential signal may be detected between the first and second pattern parts 111 and 112.

With reference back to FIG. 1, the driving circuit 120 may include a signal providing unit 121, a detection unit 122, and a controller 123. The signal providing unit 121 may provide the differential signal from each pair of row patterns of the electrode pattern 110.

The signal providing unit 121 may include a signal generator 121a, a signal modulator 121b, and a first multiplexer 121c.

The signal generator 121a may generate first and second phase difference signals (□Vdrive,p, □Vdrive,n) having a pre-set phase difference.

The signal modulator 121b may modulate the first and second phase difference signals (□Vdrive,p, □Vdrive,n) transferred from the signal generator 121a into differential signals having first and second signals (Vdrive,p, Vdrive,n) that can be provided to the electrode pattern 110.

The first multiplexer 121c may provide the differential signals transferred from the signal modulator 121b by at least a pair of selected row patterns.

The controller 122 may control the signal providing unit 121 to provide the differential signals and the detection unit 123 to detect the capacitance.

Thus, the controller 122 may include a channel scan logic unit 122a and a channel decoder 122b. The channel scan logic unit 122a may set the order of selecting row patterns of the electrode pattern 110 to which the differential signals are to be provided, the providing order and selecting column patterns for which capacitance is to be detected, and the detection order. The channel decoder 122 may control the first multiplexer 121c to select at least a pair of row patterns to provide the differential signals according to the setting of the channel scan logic unit 122a, and control the order of providing the differential signals. Also, the channel decoder 122b may control the detection unit 123 to detect capacitance.

The detection unit 123 may detect capacitance of the electrode pattern 110 under the control of the controller 122.

Thus, the detection unit 123 may include a second multiplexer 123a, a Q-V converter 123b, a noise canceler 123c, and an A/D converter 123d.

The second multiplexer 123a may select at least pair of column patterns to detect capacitance and sequentially detect capacitance of each pair of column patterns under the control of the channel decoder 122b.

The Q-V converter 123b may convert the detected capacitance into a detection signal having a voltage according to the detected capacitance.

The noise canceler 123c may buffer and filter the converted detection signal to cancel noise which can be possibly included in the detection signal.

The noise-canceled detection signal may be an analog type signal, and the A/D converter 123d may convert the analog type detection signal into a digital type detection signal.

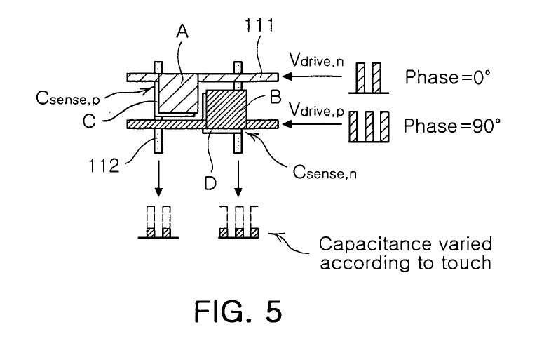

FIG. 5 illustrates the driving of electrode patterns employed for the touch screen according to an exemplary embodiment of the present invention.

With reference to FIG. 5, drive signals including first and second signals (Vdrive,p, Vdrive,n) each having a different phase may be simultaneously provided to a pair of row patterns. For example, the first and second signals (Vdrive,p, Vdrive,n) may have a phase difference of 90 degrees. However, without being limited thereto, the first and second signals (Vdrive,p, Vdrive,n) may have various other phase differences.

The electrode pads A and B of a pair of row patterns 111 may have the same area, and the electrode pads C and D of a pair of column patterns 112 corresponding to the pair of row patterns may have the same area and also may have the same area as that of the electrode pads A and B of the pair of row patterns 111. Accordingly, they have a different capacitance when compared with pad positions where the electrode pads are not formed. This is to maximize the differential effect by minimizing an interference effect due to the capacitance of the corresponding area. Namely, capacitance at a pad position where no electrode pad is formed can be extremely small when compared with capacitance of an electrode pad, so it may be assumed that there is no capacitance at a pad position where no electrode pad is formed.

Accordingly, a detection signal obtained by converting the capacitance from the column patterns may have the relationship expressed by Equation 1 shown below:

$$( \begin{matrix}{V}_{sense , p} \\ {V}_{sense , n}\end{matrix} ) = [ \begin{matrix}c & 0 \\ 0 & c\end{matrix} ] ( \begin{matrix}{V}_{drive , p} \\ {V}_{drive , n}\end{matrix} ) \qquad [ Equation 1 ]$$

Here, the first signal (Vdrive,p) may be applied to a first row pattern of a pair of row patterns, and the second signal (Vdrive,n) may be simultaneously applied to the second row pattern of the pair of row patterns, and capacitance can be simultaneously detected from a pair of column patterns.

The differential signals and the capacitance may have the relationship expressed by Equation 2 shown below:

Qₚ=(C_{sense,p}+C_{stray})V_{drive,p} Qₙ=(C_{sense,n}+C_{stray})V_{drive,n} V_{drive}=V_{drive,p}−V_{drive,n} [Equation 2]

Here, C_{stray} may be the capacitance of the pattern itself, Qp may be the capacitance of the first one of the pair of column patterns, and Qn may be the capacitance of the second one of the pair of column patterns.

In this case, because the first signal (Vdrive,p) and the second signal (Vdrive,n) may have a phase difference of 90 degrees, a differential voltage (Vsense) of the detection signal detected from the pair of column patterns may have the relationship expressed by Equation 3 shown below:

Vₛₑₙₛₑ=V_{sence,p}−V_{sence,n} [Equation 3]

Here, the first detection signal (Vsense,p) and the second detection signal (Vsense,n) may have the relationship expressed by Equation 4 shown below:

$${V}_{sense , p} = \frac{1}{1 + {C}_{{body}^{*}} / ( {C}_{sense , p} + {C}_{stray} )} {V}_{drive , p} \\ {V}_{sense , n} = \frac{1}{1 + {C}_{{body}^{*}} / ( {C}_{sense , n} + {C}_{stray} )} {V}_{drive , n} \qquad [ Equation 4 ]$$

(Here, C_{body*} may indicate a parasitic capacitance component).

As described above, the influence of noise can be drastically reduced by providing the differential signals and differentially detecting the capacitance. For example, if noise is generated in the signal provided to the pattern in the relationship of Equation 4, it may have the relationship expressed by Equation 5 shown below:

$${V}_{sense , p} = \frac{1}{1 + {C}_{{body}^{*}} / ( {C}_{sense , p} + {C}_{stray} )} ( {V}_{drive , p} + {v}_{noise} ) \\ {V}_{sense , n} = \frac{1}{1 + {C}_{{body}^{*}} / ( {C}_{sense , n} + {C}_{stray} )} ( {V}_{drive , n} + {v}_{noise} ) \\ \begin{matrix}{V}_{sense} = {V}_{sense , p} - {V}_{sense , n} \\ = \frac{1}{1 + {C}_{{body}^{*}} / ( {C}_{sense} + {C}_{stray} )} ( {V}_{drive , p} - {V}_{drive , n} )\end{matrix} \qquad [ Equation 5 ]$$

Here, it is noted that, because the areas of the electrode pads are equal, Csense,p and Csense,n are the same, so the Vnoise component is canceled out. Thus, it is noted that the noise of □ signal input to the row patterns can be canceled by providing the differential signals.

Next, noise may be generated in the patterns by an external electronic device, which affects the capacitance as expressed by Equation 6 shown below:

Qₚ=Qₚ₀+Δqₙₒᵢₛₑ Qₙ=Qₙ₀+Δqₙₒᵢₛₑ [Equation 6]

Here, Qpo may indicate the capacitance by electrode pads, and □qₙₒᵢₛₑ may indicate capacitance due to noise.

Namely, the change in the capacitance due to noise is assumed to uniformly affect the close capacitance, so the relationship expressed by Equation 7 shown below may be established:

Qₚ=(C_{sense,p}+C_{stray})V_{drive,p}+Δqₙₒᵢₛₑ Qₙ=(C_{sense,n}+C_{stray})V_{drive,n}+Δqₙₒᵢₛₑ [Equation 7]

Accordingly, the detection signals detected from the column patterns may be represented by Equation 8 shown below:

$${V}_{sense , p} = \frac{1}{1 + {C}_{{body}^{*}} / ( {C}_{sense , p} + {C}_{stray} )} {V}_{drive , p} + \frac{1}{{C}_{{body}^{*}} + {C}_{sense , p} + {C}_{stray}} Δ {q}_{noise} \\ {V}_{sense , n} = \frac{1}{1 + {C}_{{body}^{*}} / ( {C}_{sense , n} + {C}_{stray} )} {V}_{drive , n} + \frac{1}{{C}_{{body}^{*}} + {C}_{sense , n} + {C}_{stray}} Δ {q}_{noise} \qquad [ Equation 8 ]$$

The first and second detection signals (Vsense,p, Vsense,n) may form a differential voltage represented by Equation 9 shown below:

$$\begin{matrix}{V}_{sense} = {V}_{sense , p} - {V}_{sense , n} \\ = \frac{1}{1 + {C}_{{body}^{*}} / ( {C}_{sense} + {C}_{stray} )} ( {V}_{drive , p} - {V}_{drive , n} )\end{matrix} \qquad [ Equation 9 ]$$

As shown in Equation 9, it is noted that the change in the capacitance due to external noise is canceled out by the differential signal and by the differential detection.

As described above, according to the exemplary embodiments of the present invention, by providing the differential signals to the electrode patterns of the touch screen and differentially detecting the change in the capacitance due to a user contact, the influence of drive signal noise and noise from an external electronic device can be minimized, and thus, user contact can be precisely detected.

As set forth above, according to exemplary embodiments of the invention, a user selection can be accurately received by canceling noise by applying a differential signal to electrode patterns, for a touch screen, each having a different capacitance.

While the present invention has been shown and described in connection with the exemplary embodiments, it will be apparent to those skilled in the art that modifications and variations can be made without departing from the spirit and scope of the invention as defined by the appended claims.

What is claimed is:

1. An electrode pattern for a touch screen, the electric pattern comprising:
a first electrode pattern part having a plurality of row patterns disposed in rows, each of the plurality of row patterns having a plurality of pad positions prepared at pre-set intervals, the odd numbered row patterns, among the plurality of row patterns, having an electrode pad with a certain area formed at each odd-numbered pad position, and the even-numbered row patterns, among the plurality of row patterns, having an electrode pad with a certain area formed at each even-numbered pad position; and
a second electrode pattern part having a plurality of column patterns disposed in columns on a lower surface of the first electrode pattern part, each of the plurality of column patterns having a plurality of pad positions prepared at pre-set intervals and facing the plurality of pad positions of the row patterns, the odd numbered column patterns, among the plurality of column patterns, having an electrode pad with a certain area formed at each odd-numbered pad position, and the even-numbered column patterns, among the plurality of column patterns, having an electrode pad with a certain area formed at each even-numbered pad position.

2. The electrode pattern of claim 1, wherein a dielectric may be disposed between the first and second electrode pattern parts.

3. The electrode pattern of claim 1, wherein the area of the electrode pad of the first electrode pattern part is the same as that of the electrode pad of the second electrode pattern part.

4. The electrode pattern of claim 1, wherein the area of an odd-numbered electrode pad of the first electrode pattern part and that of the even-numbered electrode pad of the first electrode pattern part are the same.

5. The electrode pattern of claim 1, wherein the area of the odd-numbered electrode pad of the second electrode pattern part and that of the even-numbered electrode pad of the second electrode pattern part are the same.

6. A driver for driving a touch screen, the driver comprising:
a signal providing unit providing a differential signal having a pre-set phase difference by at least a pair of row patterns among the electrode patterns formed as a plurality of row patterns and a plurality of column patterns cross each other;
a detection unit detecting capacitance by at least a pair of row patterns among the plurality of column patterns; and
a controller controlling the signal providing unit to provide the differential signal and the detection unit to detect capacitance.

7. The driver of claim 6, wherein the signal providing unit comprises:
a signal generator generating a phase difference signal having a pre-set phase difference;
a signal modulator modulating the differential signal to supply the phase difference signal from the signal generator to the electrode patterns; and
a first multiplexer selecting at least a pair of row patterns from among the row patterns of the electrode patterns and providing the differential signal from the signal modulator by the selected pair of row patterns under the control of the controller.

8. The driver of claim 6, wherein the detection unit comprises:
a second multiplexer selecting at least a pair of column patterns from among the column patterns of the electrode patterns and receiving capacitance by the selected pair of column patterns under the control of the controller;
a Q-V converter converting the received capacitance into a detection signal having a voltage according to the capacitance;
a noise canceler canceling noise of the detection signal transferred from the Q-V converter; and
an A/D converter converting the detection signal, whose noise has been canceled by the noise canceler, into a digital signal.

9. The driver of claim 7, wherein the controller comprises:
a channel scan logic unit setting scanning of the electrode patterns; and
a channel decoder controlling the signal providing unit to select row patterns and the detection unit to select column patterns according to the setting of the channel scan logic unit.

10. The driver of claim 8, wherein the controller comprises:
a channel scan logic unit setting scanning of the electrode patterns; and
a channel decoder controlling the signal providing unit to select row patterns and the detection unit to select column patterns according to the setting of the channel scan logic unit.

11. The driver of claim 7, wherein the first multiplexer selects mutually adjacent row patterns as a pair of row patterns among the plurality of row patterns.

12. The driver of claim 8, wherein the second multiplexer selects mutually adjacent column patterns as a pair of column patterns among the plurality of column patterns.

13. A touch screen comprising:
a first electrode pattern part having a plurality of row patterns disposed in rows, each of the plurality of row patterns having a plurality of pad positions prepared at pre-set intervals, the odd numbered row patterns, among the plurality of row patterns, having an electrode pad with a certain area formed at each odd-numbered pad position, and the even-numbered row patterns, among the plurality of row patterns, having an electrode pad with a certain area formed at each even-numbered pad position;
a second electrode pattern part having a plurality of column patterns disposed in columns on a lower surface of the first electrode pattern part, each of the plurality of column patterns having a plurality of pad positions prepared at pre-set intervals and facing the plurality of pad positions of the row patterns; and
a driving circuit providing a differential signal having a pre-set phase difference by at least a pair of row patterns among the plurality of row patterns of the electrode patterns.

14. The touch screen of claim 13, wherein a dielectric is disposed between the first and second electrode pattern parts.

15. The touch screen of claim 13, wherein the area of an odd-numbered electrode pad of the first electrode pattern part and that of the even-numbered electrode pad of the first electrode pattern part are the same, and the area of the odd-numbered electrode pad of the second electrode pattern part and that of the even-numbered electrode pad of the second electrode pattern part are the same.

16. The touch screen of claim 15, wherein the area of the electrode pad of the first electrode pattern part is the same as that of the electrode pad of the second electrode pattern part.

17. The touch screen of claim 13, wherein the driving circuit comprising:
a signal providing unit providing a differential signal by at least a pair of row patterns among the electrode patterns;
a detection unit detecting capacitance by at least a pair of row patterns among the plurality of column patterns; and
a controller controlling the signal providing unit to provide the differential signal and the detection unit to detect capacitance.

18. The touch screen of claim 17, wherein the signal providing unit comprises:
a signal generator generating a phase difference signal having a pre-set phase difference;
a signal modulator modulating the differential signal to supply the phase difference signal from the signal generator to the electrode patterns; and
a first multiplexer selecting at least a pair of row patterns from among the row patterns of the electrode patterns and providing the differential signal from the signal modulator by the selected pair of row patterns under the control of the controller.

19. The touch screen of claim 17, wherein the detection unit comprises:
a second multiplexer selecting at least a pair of column patterns from among the column patterns of the electrode patterns and receiving capacitance by the selected pair of column patterns under the control of the controller;
a Q-V converter converting the received capacitance into a detection signal having a voltage according to the capacitance;
a noise canceler canceling detection signal noise transferred from the Q-V converter; and
an A/D converter converting the detection signal, whose noise has been canceled by the noise canceler, into a digital signal.

20. The touch screen of claim 18, wherein the controller comprises:
a channel scan logic unit setting the scanning of the electrode patterns; and
a channel decoder controlling the signal providing unit to select row patterns and the detection unit to select column patterns according to the setting of the channel scan logic unit.

21. The touch screen of claim 19, wherein the controller comprises:
a channel scan logic unit setting the scanning of the electrode patterns; and
a channel decoder controlling the signal providing unit to select row patterns and the detection unit to select column patterns according to the setting of the channel scan logic unit

22. The driver of claim 20, wherein the first multiplexer selects mutually adjacent row patterns as a pair of row patterns among the plurality of row patterns.

23. The driver of claim 21, wherein the second multiplexer selects mutually adjacent column patterns as a pair of column patterns among the plurality of column patterns.
